(19) United States
(12) Patent Application Publication
(10) Pub. No.: US 2025/0171351 A1
(43) Pub. Date: May 29, 2025

(54) WINDOW, DISPLAY DEVICE, AND METHOD FOR MANUFACTURING WINDOW

(71) Applicant: Samsung Display Co., LTD., Yongin-si (KR)

(72) Inventors: HYUNJI LEE, Yongin-si (KR); SANGHOON KIM, Yongin-si (KR); SEUNGHO KIM, Yongin-si (KR); SEONGJIN HWANG, Yongin-si (KR)

(21) Appl. No.: 18/793,764

(22) Filed: Aug. 3, 2024

(30) Foreign Application Priority Data
Nov. 24, 2023 (KR) 10-2023-0165569

(51) Int. Cl. C03C 21/00; H05K 5/03

(52) U.S. Cl. CPC C03C 21/002; H05K 5/03

(57) ABSTRACT

A window includes a reinforced patterned glass including a patterned portion, in which a groove pattern is defined, and a non-patterned portion adjacent to the patterned portion, where the reinforced patterned glass includes a base layer, and a compressive stress layer disposed on a top surface and a bottom surface of the base layer. A compressive stress at a surface of the reinforced patterned glass measured by an ASTM C770-16 method is equal to or greater than about 150 MPa and equal to or less than about 350 MPa, and a thickness of the compressive stress layer is equal to or greater than about 1% of a thickness of the non-patterned portion and equal to or less than about 5.5% of the thickness of the non-patterned portion.

This application claims priority to Korean Patent Application No. 10-2023-0165569, filed on Nov. 24, 2023, and all the benefits accruing therefrom under 35 U.S.C. § 119, the content of which in its entirety is herein incorporated by reference.

### BACKGROUND

### (1) Field

Embodiments of the disclosure described herein relate to a window, a display device, and a method for manufacturing the window, and more particularly, to a window including foldable, chemically strengthened patterned glass, a display device including the window, and a method for manufacturing the window.

### (2) Description of the Related Art

An electronic device such as a smartphone, a digital camera, a laptop computer, a navigation system, and a smart television that provide an image to a user may include a display device for displaying an image. The display device creates the image and provides the image to the user via a display screen.

Recently, with a technology development of the display device, various types of display devices are being developed. For example, the various display devices that may be transformed into a curved shape, folded, or rolled are being developed.

### SUMMARY

A flexible display device may include a flexible display panel and a window disposed on the display panel. The window may include patterned glass with a pattern defined therein to facilitate a folding operation thereof.

Embodiments of the disclosure provide a window including reinforced patterned glass with little changes in a volume and in a refractive index of a patterned portion.

Embodiments of the disclosure provide a display device with improved visibility by including reinforced patterned glass with little changes in a volume and in a refractive index of a patterned portion.

Embodiments of the disclosure provide a window manufacturing method including a method for chemically strengthening patterned glass such that a volume change and a refractive index change of a patterned portion are small.

According to an embodiment, a window includes a reinforced patterned glass including a patterned portion in which a groove pattern is defined, and a non-patterned portion adjacent to the patterned portion, where the reinforced patterned glass includes a base layer, and a compressive stress layer disposed on a top surface and a bottom surface of the base layer, a compressive stress at a surface of the reinforced patterned glass measured by an ASTM C770-16 method is equal to or greater than about 150 megapascals (MPa) and equal to or less than about 350 MPa, and a thickness of the compressive stress layer is equal to or greater than about 1% of a thickness of the non-patterned portion and equal to or smaller than about 5.5% of the thickness of the non-patterned portion.

In an embodiment, the reinforced patterned glass may include Na⁺ ions and K⁺ ions.

In an embodiment, a modulus of the reinforced patterned glass may be equal to or greater than about 400 MPa and equal to or less than about 700 MPa.

In an embodiment, the thickness of the non-patterned portion may be equal to or greater than about 100 micrometers (m) and equal to or less than about 400 μm.

In an embodiment, the thickness of the compressive stress layer may be equal to or greater than about 4.0 μm and equal to or less than about 5.5 μm.

In an embodiment, the groove pattern may include a plurality of grooves defined in a top surface and a bottom surface of the reinforced patterned glass.

In an embodiment, the window may further include a filler filled in recessed spaces defined by the plurality of grooves.

In an embodiment, the window may further include a window protecting layer disposed on the reinforced patterned glass.

According to an embodiment, a window includes a reinforced patterned glass including a patterned portion in which a groove pattern is defined, and a non-patterned portion adjacent to the patterned portion, where the reinforced patterned glass includes a base layer, and a compressive stress layer disposed on a top surface and a bottom surface of the base layer, and a compressive stress at a surface of the patterned portion is less than a compressive stress at a surface of the non-patterned portion.

In an embodiment, the compressive stress at the surface of the patterned portion measured by an ASTM C770-16 method may be equal to or greater than about 150 MPa and equal to or less than about 350 MPa.

In an embodiment, a thickness of a compressive stress layer of the patterned portion may be less than a thickness of a compressive stress layer of the non-patterned portion.

In an embodiment, a thickness of a compressive stress layer of the patterned portion may be equal to or greater than about 1% of a thickness of the non-patterned portion and equal to or less than about 5.5% of the thickness of the non-patterned portion.

In an embodiment, the thickness of the compressive stress layer of the patterned portion may be equal to or greater than about 4.0 μm and equal to or less than about 5.5 μm.

In an embodiment, the reinforced patterned glass may contain Na⁺ ions and K⁺ ions.

In an embodiment, a modulus of the reinforced patterned glass may be equal to or greater than about 400 MPa and equal to or less than about 700 MPa.

In an embodiment, a thickness of the non-patterned portion may be equal to or greater than about 100 μm and equal to or less than about 400 μm.

In an embodiment, the groove pattern may include a plurality of grooves defined in a top surface and a bottom surface of the reinforced patterned glass.

In an embodiment, the window may further include a filler filled in recessed spaces of the plurality of grooves.

According to an embodiment, a display device includes a display module including a foldable area folded around a folding axis on a plane and a non-foldable area adjacent to the foldable area, and a window disposed on the display module, where the window includes a reinforced patterned glass including a patterned portion corresponding to the foldable area and including a groove pattern defined therein and a non-patterned portion corresponding to the non-foldable area, the reinforced patterned glass includes a base layer, and a compressive stress layer disposed on a top surface and a bottom surface of the base layer, a compressive stress at a surface of the patterned portion measured by an ASTM C770-16 method is equal to or greater than about 150 MPa and equal to or less than about 350 MPa, and a thickness of a compressive stress layer of the patterned portion is equal to or greater than about 1% a thickness of the non-patterned portion and equal to or less than about 5.5% of the thickness of the non-patterned portion.

In an embodiment, a compressive stress at a surface of the non-patterned portion measured by the ASTM C770-16 method may be equal to or greater than about 150 MPa and equal to or less than about 350 MPa, and a thickness of a compressive stress layer of the non-patterned portion may be equal to or greater than about 1% of the thickness of the non-patterned portion and equal to or less than about 5.5% of the thickness of the non-patterned portion.

In an embodiment, the compressive stress at the surface of the patterned portion may be smaller than a compressive stress at a surface of the non-patterned portion, and the thickness of the compressive stress layer of the patterned portion may be less than a thickness of a compressive stress layer of the non-patterned portion.

According to an embodiment, a method for manufacturing a window includes preparing a patterned glass including a patterned portion having a defined groove pattern and a non-patterned portion adjacent to the patterned portion, and forming a reinforced patterned glass by providing a strengthening molten salt to the patterned glass at a temperature equal to or higher than about 340° C. and lower than about 380° C., and the strengthening molten salt includes NaNO₃ and KNO₃ in a molar ratio of about 3:7.

In an embodiment, the reinforced patterned glass may include a compressive stress layer, a compressive stress at a surface of the reinforced patterned glass measured by an ASTM C770-16 method may be equal to or greater than about 150 MPa and equal to or less than about 350 MPa, and a thickness of the compressive stress layer may be equal to or greater than about 1% of a thickness of the non-patterned portion and equal to or less than about 5.5% of the thickness of the non-patterned portion.

In an embodiment, the thickness of the compressive stress layer may be equal to or greater than about 4.0 μm and equal to or less than about 5.5 μm.

### BRIEF DESCRIPTION OF THE DRAWINGS

The above and other features of embodiments of the disclosure will become apparent by describing in detail embodiments thereof with reference to the accompanying drawings, in which:

FIG. 1 is a perspective view of a display device according to an embodiment of the disclosure;

FIGS. 2A to 2D are perspective views of a display device shown in FIG. 1 in folded states;

FIG. 3A is a perspective view of a display device according to an embodiment of the disclosure;

FIGS. 3B and 3C are perspective views of a display device shown in FIG. 3A in multi-folded states, respectively;

FIG. 4 is an exploded perspective view of an electronic device according to an embodiment of the disclosure;

FIG. 5A is a cross-sectional view of a display device cut along line I-I′ shown in FIG. 4;

FIG. 5B is an enlarged cross-sectional view of a portion A1 shown in FIG. 5A;

FIG. 6 is a cross-sectional view of a portion of a window according to an embodiment of the disclosure;

FIG. 7 is a cross-sectional view of a portion of reinforced patterned glass according to an embodiment of the disclosure;

FIG. 8 is a graph showing stress characteristics of reinforced patterned glass according to an embodiment of the disclosure;

FIG. 9 is a flowchart of a window manufacturing method according to an embodiment of the disclosure;

FIGS. 10 to 12 are views showing processes of a window manufacturing method according to an embodiment of the disclosure;

FIG. 13 is a cross-sectional view of a portion of a window according to an embodiment of the disclosure; and

FIGS. 14A to 14F are images showing results of evaluating deformation of a patterned portion of reinforced patterned glass according to Present Examples and Comparative Examples, respectively.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

As used herein, when a component (or a region, a layer, a portion, and the like) is referred to as being “on”, “connected to”, or “coupled to” another component, it means that the component may be directly disposed/connected/coupled on another component or a third component may be disposed between the component and another component.

As used herein, “directly disposed” may mean that there is no layer, film, area, plate, and the like added between a portion, such as a layer, a film, an area, a plate, and the like, and another portion. For example, “directly disposed” may mean disposed without using an additional member, such as an adhesive member, between two layers or two members.

Like reference numerals refer to like components. In addition, in the drawings, thicknesses, ratios, and dimensions of components are exaggerated for effective description of technical content.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

Terms such as first, second, and the like may be used to describe various components, but the components should not be limited by the terms. The above terms are used only for the purpose of distinguishing one component from another. For example, without departing from the scope of the disclosure, a first component may be named as a second component, and similarly, the second component may also be named as the first component.

In addition, terms such as “beneath”, “below”, “on”, “above” are used to describe the relationship of the components illustrated in the drawings. The above terms are relative concepts, and are described with reference to directions indicated in the drawings. As used herein, “disposed on” may refer to being disposed not only on top of but also beneath a member.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described with reference to the accompanying drawings.

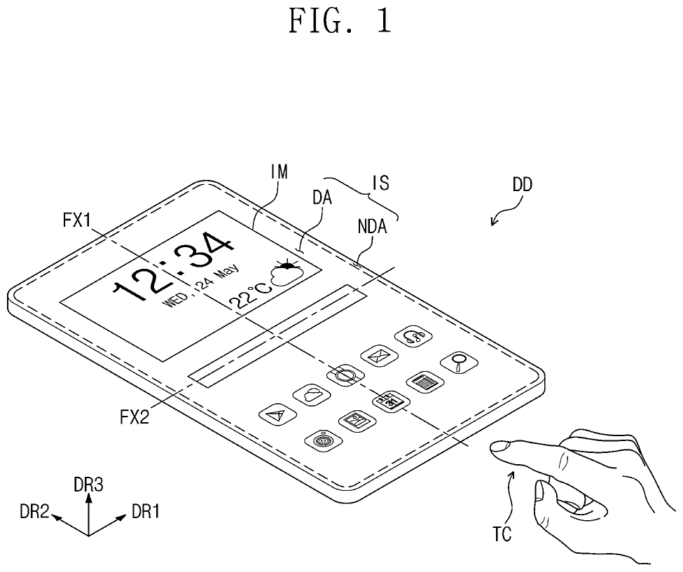

FIG. 1 is a perspective view of a display device DD according to an embodiment of the disclosure.

Referring to FIG. 1, an embodiment of the display device DD may be a device that is activated in response to an electrical signal. The display device DD may include various types of electronic device, for example, a large electronic device such as a television, a monitor, or an outdoor billboard, as well as a small and medium-sized electronic device such as a personal computer, a laptop computer, a personal digital terminal, a vehicle navigation unit, a game console, a portable electronic device, and a camera. In an embodiment, the display device DD may be a smartphone, for example, as shown in FIG. 1.

The display device DD may have a rectangular shape with a short side in a first direction DR1 and a long side in a second direction DR2 that intersects the first direction DR1. However, the shape of the display device DD may not be limited thereto, and the display devices DD of various shapes may be provided.

The display device DD may be a foldable display device. Specifically, display device DD according to an embodiment of the disclosure may be folded or foldable based on a folding axis extending in a predetermined direction. Hereinafter, a state of not being folded and being flat is defined as a first state (i.e., a non-folded state), and a state of being folded with respect to the folding axis is defined as a second state (i.e., a folded state). The folding axis is an imaginary rotation axis that occurs when the display device DD is folded and is able to be formed by a mechanical structure of the display device DD.

The folding axis may extend in the first direction DR1 or the second direction DR2. In an embodiment of the disclosure, a folding axis extending in the second direction DR2 is defined as a first folding axis FX1, and a folding axis extending in the first direction DR1 is defined as a second folding axis FX2. The display device DD may include one of the first and second folding axes FX1 and FX2. That is, the display device DD may be folded based on one of the first and second folding axes FX1 and FX2.

In an embodiment, as shown in FIG. 1, the display device DD may display an image IM on a display surface IS parallel to each of the first direction DR1 and the second direction DR2. The display surface IS on which the image IM is displayed may correspond to a front surface of the display device DD. A direction perpendicular to the display surface IS, that is, a thickness direction of the display device DD, may be referred to as a third direction DR3. The display device DD may display the image IM in the third direction DR3.

The display surface IS of the display device DD may be divided into a plurality of areas. A display area DA and a non-display area NDA may be defined in the display surface IS of the display device DD.

The display area DA may be an area where the image IM is displayed, and a user may view the image IM via the display area DA. The display area DA may have a square shape. The non-display area NDA, as an area adjacent to the display area DA, may be an area where the image IM is not displayed. A bezel area of the display device DD may be defined by the non-display area NDA. in an embodiment of the disclosure, as shown in FIG. 1, the non-display area NDA may surround the display area DA. Accordingly, a shape of the display area DA may be substantially defined by the non-display area NDA. However, this is shown as an example, and the non-display area NDA may be disposed adjacent to only one side of the display area DA or the non-display area NDA may be omitted.

The display device DD according to an embodiment of the disclosure may sense a user's input TC applied from the outside. The user's input TC includes various forms of external inputs such as a user's body part, light, a heat, or a pressure. In an embodiment, the user's input TC may be a touch or an approach of a user's hand on or to a front surface. However, this is merely an example, and as described above, the user's input TC may be provided in various forms. Further, the display device DD may sense the user's input TC applied to a side surface or a rear surface of the display device DD depending on a structure of the display device DD, and the disclosure may not be limited to any one embodiment.

The display device DD may activate the display surface IS to display the image IM and may also sense the user's input TC. In an embodiment, an area for sensing the user's input TC may be defined in the display area DA where the image IM is displayed. However, this is merely an example, and the area for sensing the user's input TC may be provided in the non-display area NDA or may be provided in all areas of the display surface IS.

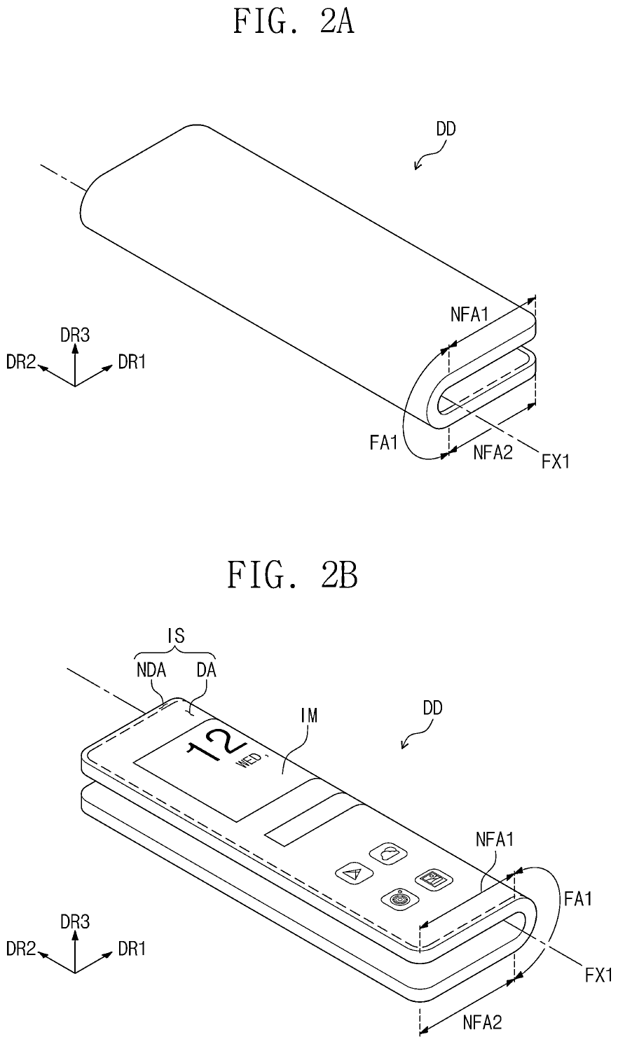

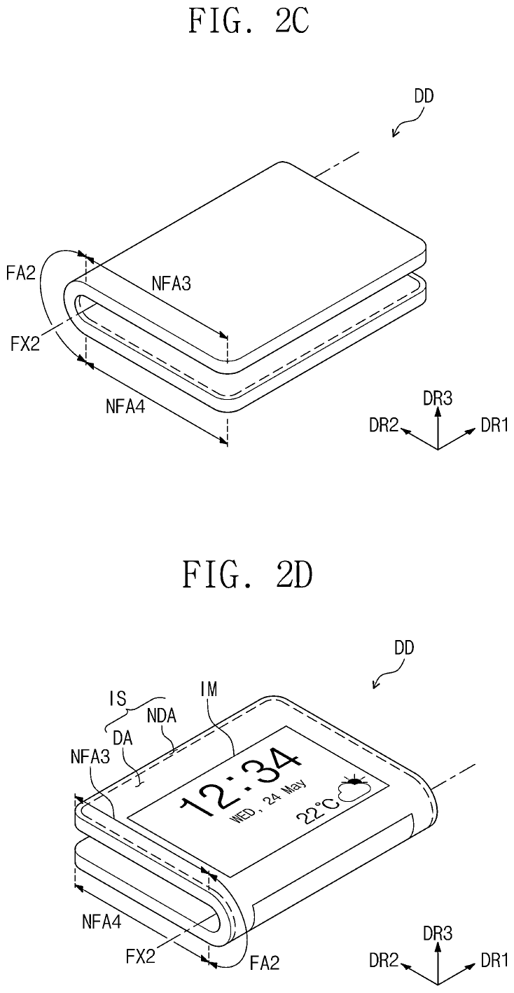

FIGS. 2A to 2D are perspective views of the display device DD shown in FIG. 1 in folded states. FIG. 2A is a diagram showing the display device DD shown in FIG. 1 in an in-folded state along the first folding axis FX1, and FIG. 2B is a diagram showing the display device DD shown in FIG. 1 in an out-folded state along the first folding axis FX1. FIG. 2C is a diagram showing the display device DD shown in FIG. 1 in the in-folded state along the second folding axis FX2, and FIG. 2D is a diagram showing the display device DD shown in FIG. 1 in the out-folded state along the second folding axis FX2.

Referring to FIGS. 2A to 2D, an embodiment of the display device DD may be a foldable display device. The display device DD may be folded based on the folding axis extending in the predetermined direction, for example, the first folding axis FX1 or the second folding axis FX2.

Referring to FIGS. 2A and 2B, in an embodiment, the plurality of areas may be defined in the display device DD based on an operating shape. The plurality of areas may be divided into a foldable area FA1 and one or more non-foldable areas NFA1 and NFA2. The foldable area FA1 may be defined between the two non-foldable areas NFA1 and NFA2.

The foldable area FA1, as an area that is folded based on the first folding axis FX1, may be an area that substantially forms a curvature. In this regard, the first folding axis FX1 may extend along the second direction DR2, that is, a direction of the long side of the display device DD. The foldable area FA1 may be defined as an area that is folded along the first folding axis FX1 and extending in the second direction DR2.

In an embodiment of the disclosure, the non-foldable areas NFA1 and NFA2 may include the first non-foldable area NFA1 and the second non-foldable area NFA2. The first non-foldable area NFA1 may be adjacent to one side of the foldable area FA1 in the first direction DR1, and the second non-foldable area NFA2 may be adjacent to the other side of the foldable area FA1 in the first direction DR1.

The display device DD may be in-folded or out-folded. Folding performed in a way such that display surfaces of the non-foldable areas NFA1 and NFA2 different from each other face each other may be defined as the in-folding, and folding performed in a way such that the display surfaces of the non-foldable areas NFA1 and NFA2 different from each other face the outside may be defined as the out-folding.

In this regard, the in-folding may refer to folding performed such that portions of the display surface IS (see FIG. 1) face each other, and the out-folding may refer to folding performed such that portions of the rear surface of the display device DD face each other.

The display device DD shown in FIG. 2A may be in-folded such that the display surface IS (see FIG. 1) of the first non-foldable area NFA1 and the display surface IS (see FIG. 1) of the second non-foldable area NFA2 face each other. As the first non-foldable area NFA1 rotates clockwise along the first folding axis FX1, the display device DD may be in-folded. To in-fold the display device DD such that the first non-foldable area NFA1 and the second non-foldable area NFA2 are aligned, the first folding axis FX1 may be defined at a center of the display device DD based on the first direction DR1.

Referring to FIG. 2B, the display device DD may be out-folded based on the first folding axis FX1. The display device DD may display the image IM when the display surface of the first non-foldable area NFA1 and the display surface of the second non-foldable area NFA2 are exposed to the outside. In addition, the display surface of the foldable area FA1 exposed to the outside may also display the image IM. As shown in FIG. 1, the display device DD may display the image IM in the unfolded state. The first non-foldable area NFA1, the second non-foldable area NFA2, and the foldable area FA1 may respectively display images that provide independent information or may respectively display portions of one image that provide one information.

The display device DD may be manufactured to have both the in-folded state and the out-folded state, or may be manufactured to have one of the in-folded state and the out-folded state.

Referring to FIGS. 2C and 2D, in an embodiment, the display device DD may be in-folded or out-folded based on the second folding axis FX2. The second folding axis FX2 may extend along the first direction DR1, that is, a direction of the short side of the display device DD.

The plurality of areas may be defined in the display device DD based on the operating shape. The plurality of areas may be divided into a foldable area FA2 and one or more non-foldable areas NFA3 and NFA4. The foldable area FA2 may be defined between the two non-foldable areas NFA3 and NFA4.

The foldable area FA2, as an area that is folded based on the second folding axis FX2, may be an area that substantially forms the curvature. The foldable area FA2 may be defined as an area that is folded along the second folding axis FX2 and extends in the first direction DR1.

In an embodiment of the disclosure, the non-foldable areas NFA3 and NFA4 may include the first non-foldable area NFA3 and the second non-foldable area NFA4. The first non-foldable area NFA3 may be adjacent to one side of the foldable area FA2 in the second direction DR2, and the second non-foldable area NFA4 may be adjacent to the other side of the foldable area FA2 in the second direction DR2.

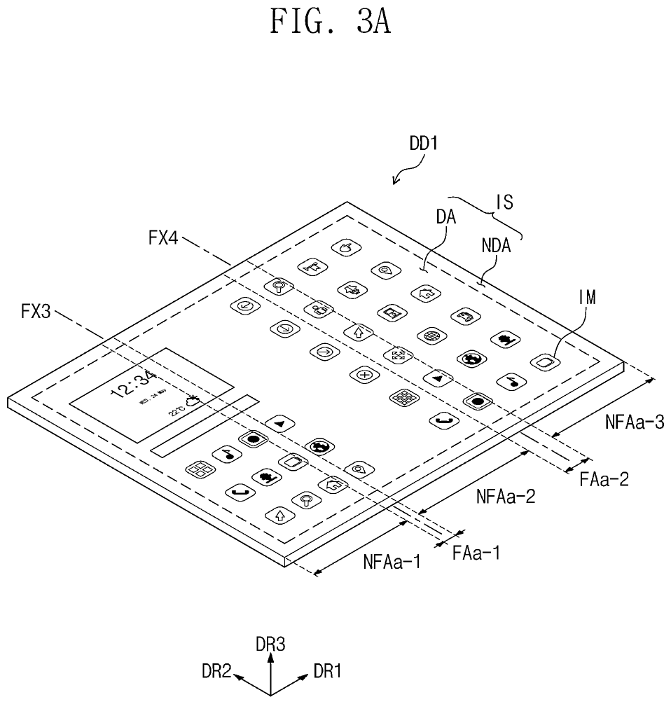

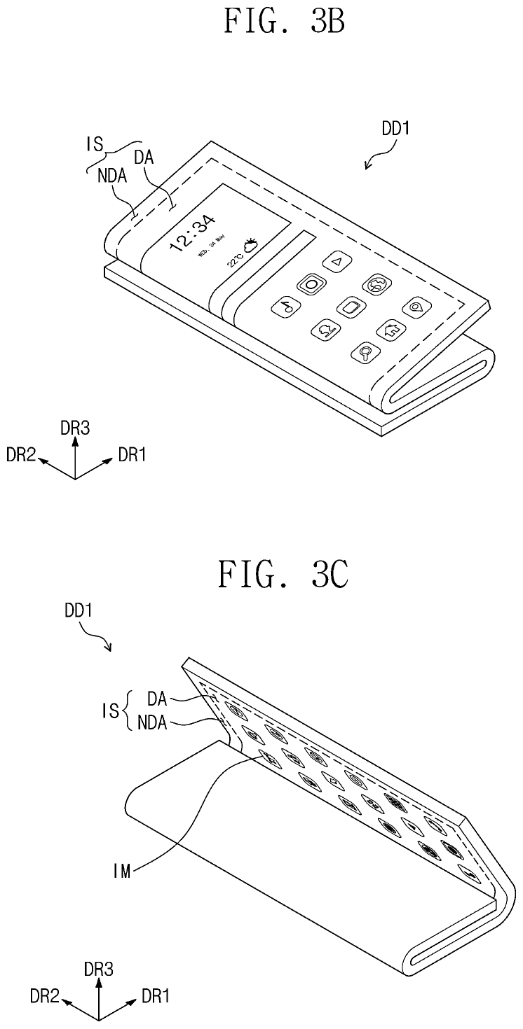

FIG. 3A is a perspective view of a display device DD1 according to an embodiment of the disclosure. FIGS. 3B and 3C are perspective views of the display device DD1 shown in FIG. 3A in multi-folded states, respectively.

Referring to FIGS. 3A to 3C, an embodiment of the display device DD1 may be a multi-foldable display device. A plurality of foldable areas may be defined in the display device DD1. The display device DD1 may include a plurality of foldable areas FAa-1 and FAa-2 and a plurality of non-foldable areas NFAa-1, NFAa-2, and NFAa-3. In an embodiment of the disclosure, the display device DD1 may include the first foldable area FAa-1, the second foldable area FAa-2, the first non-foldable area NFAa-1, the second non-foldable area NFAa-2, and the third non-foldable area NFAa-3. In the first direction DR1, the first foldable area FAa-1 is disposed between the first non-foldable area NFAa-1 and the second non-foldable area NFAa-2, and the second foldable area FAa-2 is disposed between the second non-foldable area NFAa-2 and the third non-foldable area NFAa-3. In an embodiment, for example, the two foldable areas FAa-1 and FAa-2 and the three non-foldable areas NFAa-1, NFAa-2, and NFAa-3 may be defined as shown in FIGS. 3A to 3C, but the number of foldable areas FAa-1 and FAa-2 and the number of non-foldable areas NFAa-1, NFAa-2, and NFAa-3 may not be limited thereto and may increase further.

Referring to FIGS. 3A and 3B, in an embodiment, the first foldable area FAa-1 may be folded based on a third folding axis FX3 parallel to the second direction DR2. The first foldable area FAa-1 may be in-folded such that a display surface of the second non-foldable area NFAa-2 faces a display surface of the first non-foldable area NFAa-1. The second foldable area FAa-2 may be folded based on a fourth folding axis FX4 parallel to the second direction DR2. The second foldable area FAa-2 may be out-folded such that a rear surface of the second non-foldable area NFAa-2 and a rear surface of the third non-foldable area NFAa-3 face each other and a display surface of the third non-foldable area NFAa-3 faces the outside.

Referring to FIGS. 3A and 3C, in an embodiment, the first foldable area FAa-1 may be folded based on the third folding axis FX3 parallel to the second direction DR2. The first foldable area FAa-1 may be in-folded such that the display surface of the first non-foldable area NFAa-1 is disposed inside and the display surface of the second non-foldable area NFAa-2 faces the display surface of the first non-foldable area NFAa-1. The second foldable area FAa-2 may be folded based on the fourth folding axis FX4 parallel to the second direction DR2. The second foldable area FAa-2 may be in-folded such that a rear surface of the first non-foldable area NFAa-1 and the display surface of the third non-foldable area NFAa-3 face each other.

In an embodiment of the disclosure, the out-folding operation and the in-folding operation may both be performed by the display device DD1, or only one of the out-folding operation and the in-folding operation may be performed by the display device DD1.

Although the multi-folded states of the display device DD1 are shown in FIGS. 3B and 3C, the disclosure may not be limited thereto and the display device DD1 may have various folded shapes.

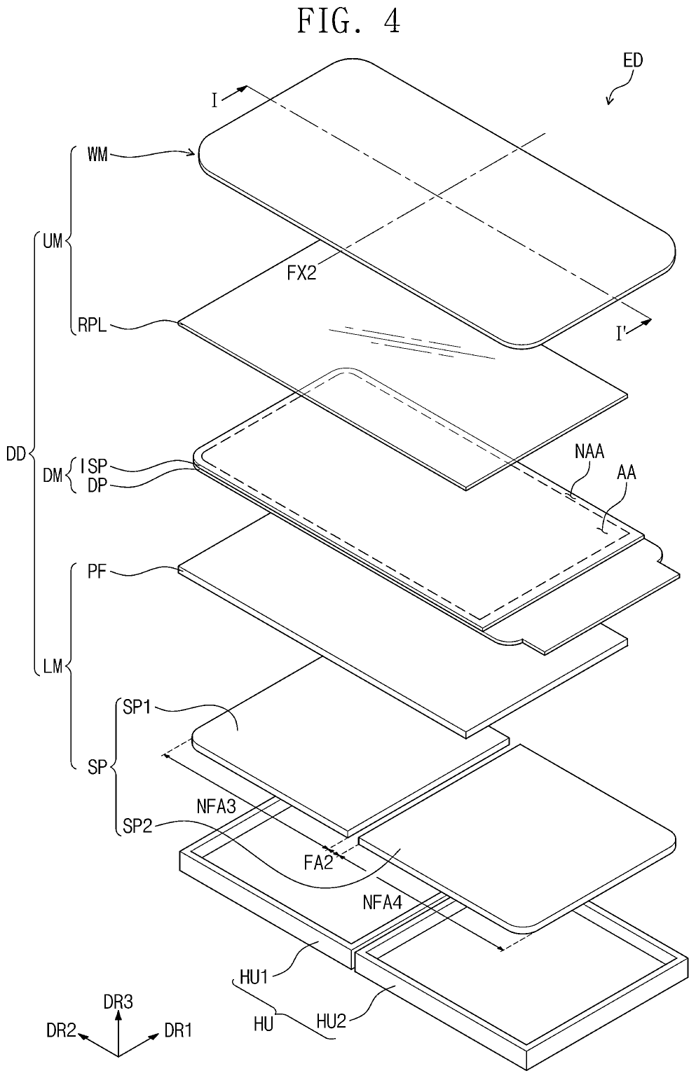

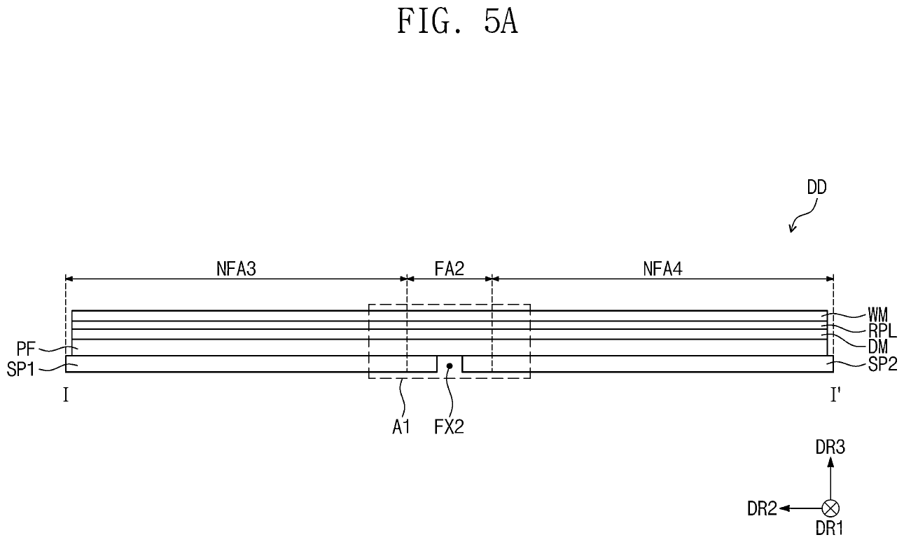

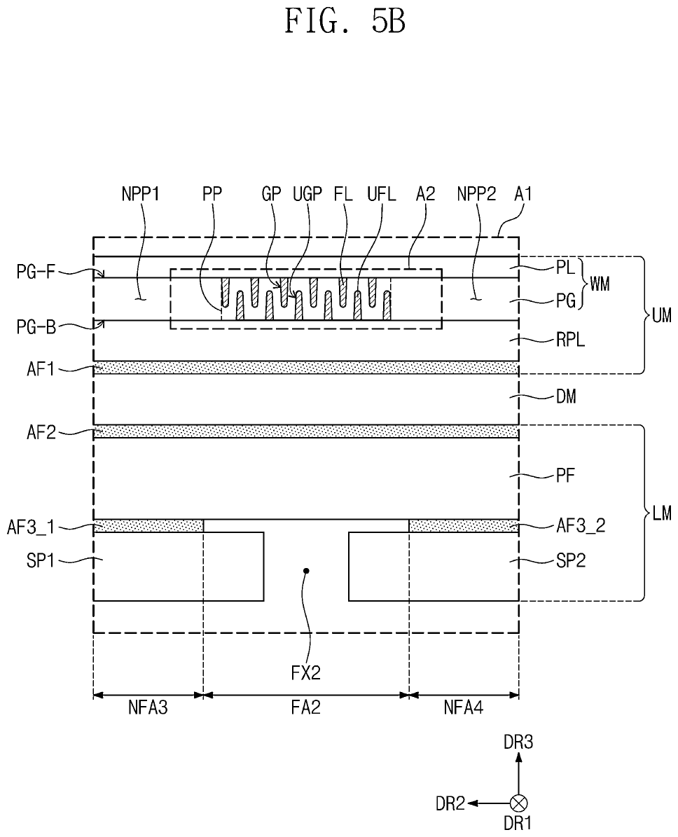

FIG. 4 is an exploded perspective view of an electronic device ED according to an embodiment of the disclosure. FIG. 5A is a cross-sectional view of the display device DD cut along line I-I′ shown in FIG. 4. FIG. 5B is an enlarged cross-sectional view of a portion A1 shown in FIG. 5A.

Referring to FIGS. 4, 5A, and 5B, the electronic device ED according to an embodiment of the disclosure includes the display device DD and a housing HU. Although not separately shown, the electronic device ED may further include a mechanism structure (or a hinge structure) for controlling a folding operation (or a bending operation) of the display device DD.

The display device DD according to an embodiment of the disclosure may include a display module DM that displays the image, an upper module UM disposed on the display module DM, and a lower module LM disposed beneath the display module DM. The display module DM may constitute a portion of the display device DD, and in particular, the image may be displayed by the display module DM.

The display module DM may include a display panel DP and an input sensing unit ISP. The display panel DP according to an embodiment of the disclosure may be a light-emitting display panel, but the disclosure may not be particularly limited thereto. In an embodiment, for example, the display panel DP may be an organic light-emitting display panel, an inorganic light-emitting display panel, or a quantum dot light-emitting display panel. A light-emitting layer of the organic light-emitting display panel may include an organic light-emitting material, and a light-emitting layer of the inorganic light-emitting display panel may include an inorganic light-emitting material. A light-emitting layer of the quantum dot light-emitting display panel may include quantum dots, quantum rods, or the like. Hereinafter, for convenience of description, embodiment where the display panel DP the organic light-emitting display panel will be described in detail, but not being limited thereto.

The display panel DP may be a flexible display panel. Accordingly, the display panel DP may be entirely rolled (or unrolled) or folded (or unfolded) around the folding axis FX2.

The input sensing unit ISP may be disposed directly on the display panel DP. According to an embodiment of the disclosure, the input sensing unit ISP may be formed on the display panel DP by a continuous process. In such an embodiment, the input sensing unit ISP may be disposed directly on the display panel DP, and an adhesive film is not disposed between the input sensing unit ISP and the display panel DP. However, the disclosure is not limited thereto. In another embodiment, the adhesive film may be disposed between the input sensing unit ISP and the display panel DP. In such an embodiment, the input sensing unit ISP may not be manufactured by the continuous process with the display panel DP, but may be manufactured via a separate process from the display panel DP and then fixed to a top surface of the display panel DP with the adhesive film.

The display panel DP creates the image and the input sensing unit ISP acquires coordinate information on the user's input (e.g., a touch event).

The upper module UM may include a window WM disposed on the display module DM. The window WM may include an optically transparent insulating material. Accordingly, the image created in the display module DM may be easily recognized by the user through the window WM.

The window WM may include reinforced patterned glass PG.

In an embodiment, as shown in FIG. 5B, the reinforced patterned glass PG may include a patterned portion PP and non-patterned portions NPP1 and NPP2. The patterned portion PP may be a portion corresponding to the foldable area FA2, and the non-patterned portions NPP1 and NPP2 may be portions respectively corresponding to the first and second non-foldable areas NFA3 and NFA4. The non-patterned portions NPP1 and NPP2 may include the first non-patterned portion NPP1 corresponding to the first non-foldable area NFA3 and the second non-patterned portion NPP2 corresponding to the second non-foldable area NFA4. The patterned portion PP may be disposed between the first and second non-patterned portions NPP1 and NPP2.

The patterned glass PG may include a top surface PG-F and a bottom surface PG-B. The top surface PG-F and the bottom surface PG-B refer to two surfaces opposite to each other in the patterned glass PG, and for example, may be two surfaces opposite to each other in the third direction DR3. In the patterned glass PG, with respect to the third direction DR3, a surface adjacent to an anti-reflection layer RPL or the display module DM may be the bottom surface PG-B and a surface adjacent to a window protecting layer PL may be the top surface PG-F.

The patterned portion PP may include a plurality of groove patterns GP and a plurality of lower groove patterns UGP. In an embodiment, the groove patterns GP may be defined in the top surface PG-F of the patterned glass PG, and the lower groove patterns UGP may be defined in the bottom surface PG-B of the patterned glass PG. The groove patterns GP may include a plurality of grooves defined in the top surface PG-F of the patterned glass PG, and the lower groove patterns UGP may include a plurality of grooves defined in the bottom surface PG-B of the patterned glass PG. The groove patterns GP may have a shape recessed from the top surface PG-F of the patterned glass PG. The lower groove patterns UGP may have a shape recessed from the bottom surface PG-B of the patterned glass PG.

In an embodiment of the disclosure, where the folding axis FX2 extends in the first direction DR1, the groove patterns GP may be arranged to be spaced apart from each other in the second direction DR2, and the lower groove patterns UGP may be arranged to be spaced apart from each other in the second direction DR2. In an embodiment, where the folding axis FX2 extends in the second direction DR2, the groove patterns GP may be arranged to be spaced apart from each other in the first direction DR1, and the lower groove patterns UGP may be arranged to be spaced apart from each other in the first direction DR1.

In an embodiment, the window WM may further include a filler FL and a lower filler UFL. In such an embodiment, the groove patterns GP and the lower groove patterns UGP may be filled by the filler FL and the lower filler UFL, respectively. The filler FL may fill the groove patterns GP, and the lower filler UFL may fill the lower groove patterns UGP. In other words, a recessed space defined by the groove patterns GP may be filled by the filler FL, and the recessed space defined by the lower groove patterns UGP may be filled by the lower filler UFL. Accordingly, the window WM may have a flat surface because of the filler FL and the lower filler UFL. The filler FL and the lower filler UFL may be provided only in the patterned portion PP and may not be provided in the first and second non-patterned portions NPP1 and NPP2.

The window WM may further include the window protecting layer PL. The window protecting layer PL may be disposed on the reinforced patterned glass PG. The window protecting layer PL may be disposed on the filler FL. The window protecting layer PL may perform a function of protecting the reinforced patterned glass PG from an external impact. The window protecting layer PL may include a synthetic resin material. The window protecting layer PL may include at least one selected from a urethane-based resin, an epoxy-based resin, a polyester-based resin, a polyether-based resin, an acrylate-based resin, an acrylonitrile-butadiene-styrene resin (ABS resin), and rubber. In an embodiment, for example, the window protecting layer PL may include at least one selected from phenylene, polyethyleneterephthalate (PET), polyimide (PI), polyamide (PAI), polyethylene naphthalate (PEN), and polycarbonate (PC).

Although not shown in the drawing, the window WM may further include a first window adhesive layer and a second window adhesive layer. The first window adhesive layer may be disposed between the reinforced patterned glass PG and the window protecting layer PL to attach the window protecting layer PL to the reinforced patterned glass PG. The second window adhesive layer may couple the window WM to a member disposed beneath the window WM. The first window adhesive layer and the second window adhesive layer may include an optically transparent adhesive material. In an embodiment, for example, each of the first window adhesive layer and the second window adhesive layer may include a pressure sensitive adhesive (PSA), an optical clear adhesive (OCA), or an optical clear resin (OCR).

The window WM may be folded or unfolded around the folding axis FX2. In other words, a shape of the window WM may be changed along with a shape change of the display module DM. The window WM transmits the image from the display module DM, and also alleviates the external impact, thereby effectively preventing the display module DM from being damaged or malfunctioning by the external impact. The external impact refers to a force from the outside that may be expressed as a pressure, a stress, or the like that causes a defect in the display module DM.

The upper module UM may further include one or more functional layers disposed between the display module DM and the window WM. In an embodiment, for example, the functional layer may be the anti-reflection layer RPL that blocks external light reflection.

The anti-reflection layer RPL may effectively prevent a problem or defect of elements constituting the display module DM being visible from the outside by external light incident through the front surface of the display device DD. The anti-reflection layer RPL may include a retarder and a polarizer. The retarder may be of a film type or a liquid crystal coating type, and may include a λ/2 retarder and/or a λ/4 retarder. The polarizer may also be of the film type or the liquid crystal coating type. The film type may include a stretched synthetic resin film, and the liquid crystal coating type may include liquid crystals arranged in a predetermined arrangement. The retarder and the polarizer may be implemented as one polarizing film. The functional layer may further include a protective film disposed on or under the anti-reflection layer RPL.

The upper module UM may further include a first adhesive film AF1 disposed between the anti-reflection layer RPL and the display module DM. The first adhesive film AF1 may include the optically transparent adhesive material. In an embodiment, for example, the first adhesive film AF1 may include the pressure sensitive adhesive (PSA), the optical clear adhesive (OCA), or the optical clear resin (OCR).

The display module DM may display the image in response to the electrical signal and transmit/receive information on the external input. The display module DM may include an active area AA and a peripheral area NAA. The active area AA may be defined as an area that emits the image provided by the display module DM.

The peripheral area NAA may be adjacent to the active area AA. In an embodiment, for example, the peripheral area NAA may surround the active area AA. However, this is merely an example. The peripheral area NAA may be defined in various shapes and the disclosure may not be limited to any one embodiment. The active area AA of the display module DM may correspond to at least a portion of the display area DA (see FIG. 1).

The lower module LM may include a support plate SP disposed on a rear surface of the display module DM and supporting the display module DM. The support plate SP may include a number of support plates corresponding to the non-foldable areas NFA3 and NFA4. In an embodiment of the disclosure, the support plate SP may include a first support plate SP1 and a second support plate SP2 disposed to be spaced apart from the first support plate SP1.

The first and second support plates SP1 and SP2 may be disposed to correspond to the first and second non-foldable areas NFA3 and NFA4, respectively. The first support plate SP1 may be disposed to correspond to the first non-foldable area NFA3 of the display module DM, and the second support plate SP2 may be disposed to correspond to the second non-foldable area NFA4 of the display module DM. Each of the first and second support plates SP1 and SP2 may include a metal material or a plastic material.

When the display module DM is in the unfolded first state, the first and second support plates SP1 and SP2 are arranged to be spaced apart from each other in the second direction DR2. When the display module DM is in the second state of being folded based on the folding axis FX2, the first and second support plates SP1 and SP2 may be arranged to be spaced apart from each other in the third direction DR3.

The first and second support plates SP1 and SP2 may be spaced apart from each other with respect to the foldable area FA2. The first and second support plates SP1 and SP2 may partially overlap the foldable area FA2. That is, a separation distance between the first and second support plates SP1 and SP2 in the second direction DR2 may be less than a width of the foldable area FA2.

The support plate SP may further include a connecting module for connecting the first and second support plates SP1 and SP2 to each other. The connecting module may include a hinge module or a multi-joint module.

In an embodiment, as shown in FIG. 4, the support plate SP may include the two support plates SP1 and SP2, but the disclosure is not limited thereto. In an embodiment, where there are the plurality of folding axes, the support plate SP may include a plurality of support plates separated based on the plurality of folding axes. In an embodiment, the support plate SP may be formed in an integrated shape rather than being separated into the first and second support plates SP1 and SP2. In such an embodiment, the support plate SP may include a bendable portion corresponding to the foldable area FA2. The bendable portion may be provided with an opening defined through the support plate SP or may have a groove recessed from one surface of the support plate SP.

The lower module LM may further include a protective film PF disposed between the display module DM and the support plate SP. The protective film PF may be a layer disposed beneath the display module DM to protect the rear surface of the display module DM. The protective film PF may include a synthetic resin film. In an embodiment, for example, the protective film PF may be a polyimide film or a polyethylene terephthalate film. However, this is merely an example and the protective film PF is not limited to the above example.

The lower module LM may further include a second adhesive film AF2 disposed between the protective film PF and the display module DM, and a third adhesive film AF3_1 and AF3_2 disposed between the protective film PF and the support plate SP. The protective film PF may be attached to the rear surface of the display module DM by the second adhesive film AF2. The third adhesive film AF3_1 and AF3_2 may include the first sub-adhesive film AF3_1 and the second sub-adhesive film AF3_2. The first sub-adhesive film AF3_1 may be disposed between the first support plate SP1 and the protective film PF, and the second sub-adhesive film AF3_2 may be disposed between the second support plate SP2 and the protective film PF. The first and second sub-adhesive films AF3_1 and AF3_2 may be spaced apart from each other with the foldable area FA2 interposed therebetween.

Each of the second and third adhesive films AF2, AF3_1, and AF3_2 may include the optically transparent adhesive material. In an embodiment, for example, each of the second and third adhesive films AF2, AF3_1, and AF3_2 may include the pressure sensitive adhesive (PSA), the optical clear adhesive (OCA), or the optical clear resin (OCR).

The housing HU may be coupled to the display device DD, e.g., to the window WM, to accommodate other modules (i.e., the display module DM, the lower module LM, and the like). In an embodiment, as shown in FIG. 4, the housing HU may include first and second housings HU1 and HU2 that are separated from each other, but the disclosure is not limited thereto. The electronic device ED may further include the hinge structure (not shown) for connecting the first and second housings HU1 and HU2 to each other.

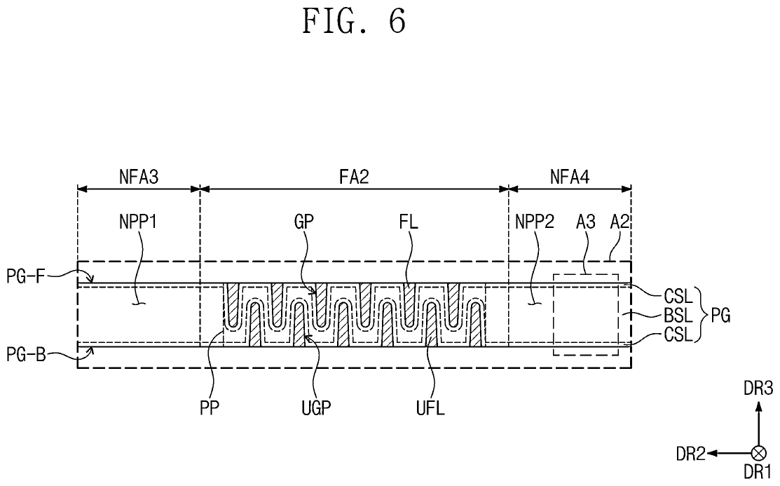

FIG. 6 is a cross-sectional view of a portion of the window WM according to an embodiment of the disclosure. FIG. 6 is an enlarged cross-sectional view of a portion A2 in FIG. 5B. FIG. 6 shows the reinforced patterned glass PG, the filler FL, and the lower filler UFL among the components of the window WM.

Referring to FIG. 6, in an embodiment, the reinforced patterned glass PG may include the patterned portion PP corresponding to the foldable area FA2. The patterned portion PP may include the plurality of groove patterns GP and the plurality of lower groove patterns UGP. The groove patterns GP may be in a groove shape recessed from the top surface PG-F of the reinforced patterned glass PG. The lower groove patterns UGP may be in a groove shape recessed from the bottom surface PG-B of the reinforced patterned glass PG.

However, the pattern defined in the patterned portion PP is not limited thereto. In an embodiment, for example, only the groove pattern GP may be defined and the lower groove pattern UGP may not be defined in the patterned portion PP. Alternatively, the groove pattern GP may not be defined and only the lower groove pattern UGP may be defined in the patterned portion PP. Alternatively, a hole pattern that extends through the reinforced patterned glass PG in the third direction DR3 may be defined in the patterned portion PP.

Each of the groove patterns GP and the lower groove patterns UGP may have a stripe shape extending in a direction parallel to the folding axis FX2 (see FIG. 5B) (i.e., the first direction DR1) in a plan view or when viewed in the third direction DR3. The groove patterns GP may be arranged to be spaced apart from each other in the second direction DR2, and the lower groove patterns UGP may be arranged to be spaced apart from each other in the second direction DR2.

The groove patterns GP and the lower groove patterns UGP may be filled by the filler FL and the lower filler UFL, respectively. In an embodiment, the recessed space defined by the groove patterns GP may be filled by the filler FL, and the recessed space defined by the lower groove patterns UGP may be filled by the lower filler UFL.

The filler FL and the lower filler UFL may be provided for preventing phenomena such as diffuse reflection and scattering caused by the groove pattern GP and the lower groove pattern UGP of the patterned portion PP.

Each of the filler FL and the lower filler UFL may include a synthetic resin material. In an embodiment, each of the filler FL and the lower filler UFL may include at least one selected from the urethane-based resin, the epoxy-based resin, the polyester-based resin, the polyether-based resin, the acrylate-based resin, the acrylonitrile-butadiene-styrene resin (ABS resin), and the rubber. In an embodiment, for example, each of the filler FL and the lower filler UFL may include at least one selected from phenylene, polyethyleneterephthalate (PET), polyimide (PI), polyamide (PAI), polyethylene naphthalate (PEN), and polycarbonate (PC).

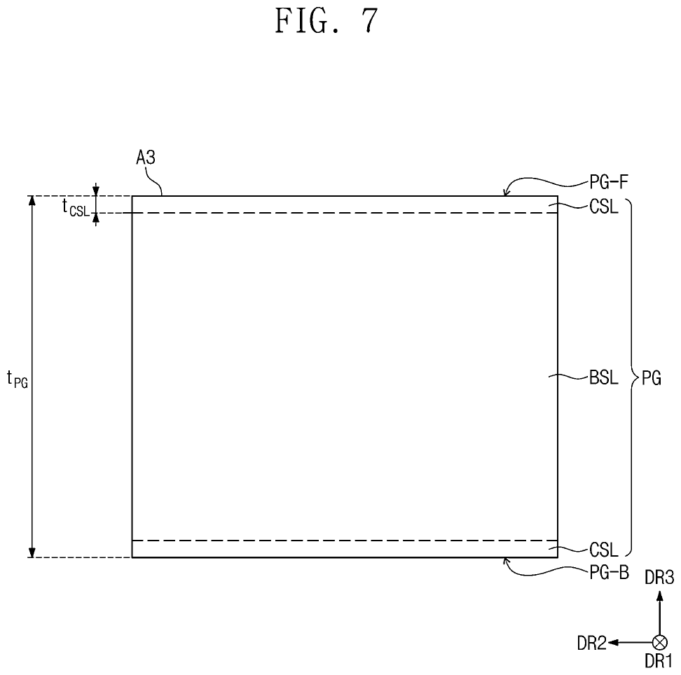

The reinforced patterned glass PG may include a base layer BSL and a compressive stress layer CSL. The compressive stress layer CSL may be disposed on at least one of a top surface and a bottom surface of the base layer BSL. In an embodiment, as shown in FIG. 6, the compressive stress layer CSL may be disposed on both the top surface and the bottom surface of the base layer BSL. However, this is merely an example, and the compressive stress layer CSL may be disposed only on one of the top surface of the base layer BSL and the bottom surface of the base layer BSL. In the patterned portion PP, the compressive stress layer CSL may be disposed on the top surface of the base layer BSL along the groove pattern GP and disposed on the bottom surface of the base layer BSL along the lower groove pattern UGP. The base layer BSL and the compressive stress layer CSL will be described in detail later in FIG. 7.

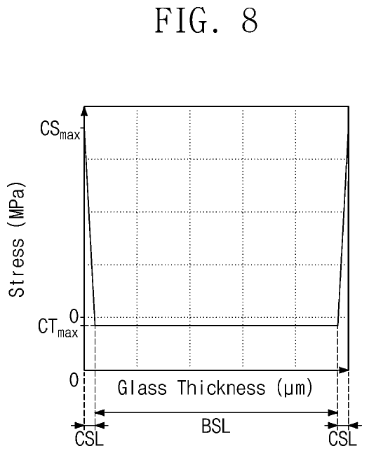

FIG. 7 is a cross-sectional view of a portion of the reinforced patterned glass PG according to an embodiment of the disclosure. FIG. 8 is a graph showing stress characteristics of the reinforced patterned glass PG according to an embodiment of the disclosure. FIG. 7 is an enlarged cross-sectional view of a portion A3 shown in FIG. 6, and FIG. 8 is a graph schematically showing a compressive stress versus a depth of the reinforced patterned glass PG.

The reinforced patterned glass PG may include tempered glass including Na⁺ ions and K⁺ ions. Concentrations of the Na⁺ ions and the K⁺ ions included in the reinforced patterned glass PG may vary depending on a depth. The reinforced patterned glass PG may be formed from a method for manufacturing the window WM according to an embodiment to be described below.

The base layer BSL may be a layer having a constant compressive stress value. The base layer BSL may have a negative compressive stress value. That is, tension may act on the base layer BSL. The compressive stress layer CSL may be a layer in which the compressive stress value thereof varies depending on the depth.

A compressive stress CSₘₐₓ at a surface of the reinforced patterned glass PG may be equal to or greater than about 150 megapascals (MPa) and equal to or less than about 350 MPa. When the compressive stress CSₘₐₓ at the surface is within the above range, durability of the reinforced patterned glass PG may be secured and a volume change and a refractive index change resulting from chemical strengthening may be minimized. Specifically, when the compressive stress CSₘₐₓ at the surface is lower than about 150 MPa, a strength of the reinforced patterned glass PG for application to the window WM may not be sufficient. When the chemical strengthening is performed such that the compressive stress CSₘₐₓ at the surface exceeds about 350 MPa, the reinforced patterned glass PG becomes curved because of the volume change of the patterned portion PP, and a difficulty of correcting the refractive index increases, which may cause a visibility problem.

A total thickness t_{PG} of the reinforced patterned glass PG may be equal to or greater than about 100 micrometers (m) and equal to or less than about 400 μm. In this regard, the total thickness t_{PG} of the reinforced patterned glass PG may mean a thickness of the non-patterned portions NPP1 and NPP2 (see FIG. 6). A thickness t_{CSL} of the compressive stress layer CSL may be equal to or greater than about 1% and equal to or less than about 5.5% of the thickness of the non-patterned portions NPP1 and NPP2 (see FIG. 6). The thickness t_{CSL} of the compressive stress layer CSL may be equal to or greater than about 4.0 μm and equal to or less than about 5.5 μm. When the thickness t_{CSL} of the compressive stress layer CSL is within the above range, the volume change and the refractive index change of the patterned portion PP are reduced, thereby improving visibility and reducing the difficulty of correcting the refractive index. Specifically, when the thickness t_{CSL} of the compressive stress layer CSL is less than about 4.0 μm, it may be difficult to suppress growth of cracks when the cracks occur. When the thickness t_{CSL} of the compressive stress layer CSL exceeds about 5.5 am, the reinforced patterned glass PG becomes curved because of the volume change of the patterned portion PP and the difficulty of correcting the refractive index increases, which may cause the visibility problem.

A modulus (e.g., Young's modulus) of the reinforced patterned glass PG may be equal to or greater than about 400 MPa and equal to or less than about 700 MPa. When the modulus of the reinforced patterned glass PG is within the above range, durability and folding reliability appropriate for application to the foldable window WM may be satisfied.

Herein, the compressive stress refers to a value measured via a surface stress meter (FSM-6000LE, Orihara) using an ASTM C770-16 (standard test) method. The surface of the reinforced patterned glass PG may represent at least one of the top surface PG-F and the bottom surface PG-B. In FIG. 8, the surface of the reinforced patterned glass PG may mean a point where the depth is zero (0).

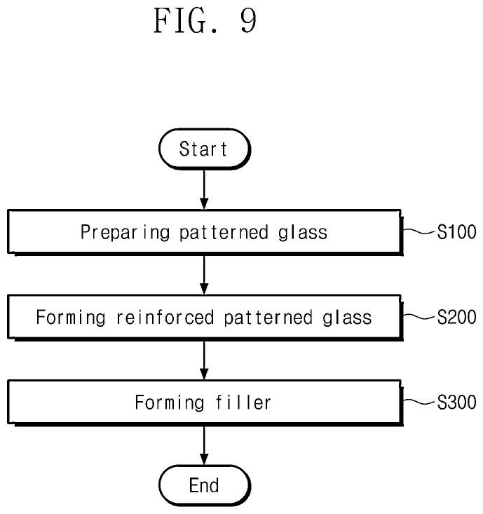

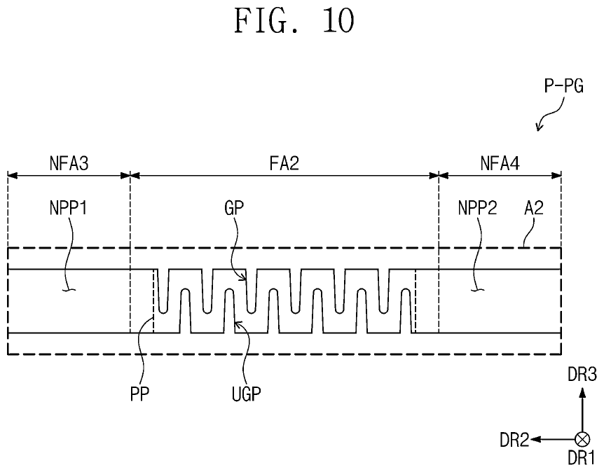

FIG. 9 is a flowchart of a window manufacturing method according to an embodiment of the disclosure. FIGS. 10 to 12 are views showing processes of a window manufacturing method according to an embodiment of the disclosure.

Referring to FIG. 9, the window manufacturing method according to an embodiment may include preparing patterned glass P-PG (S100) and forming the reinforced patterned glass PG (S200). The window manufacturing method according to an embodiment may further include forming the filler (S300).

FIG. 10 shows the prepared patterned glass P-PG (S100). The patterned glass P-PG may be defined as a glass substrate with a pattern engraved therein to improve flexibility of the glass substrate. The patterned glass P-PG may be thicker than an ultra-thin glass substrate known in the art or commercially available to have higher impact resistance and may include the pattern to have the flexibility. The patterned glass P-PG may refer to a glass before the chemical strengthening is performed thereto.

The patterned glass P-PG may include the patterned portion PP corresponding to the foldable area FA2 and the non-patterned portions NPP1 and NPP2 corresponding to the non-foldable areas NFA3 and NFA4. The non-patterned portions NPP1 and NPP2 may include the first non-patterned portion NPP1 corresponding to the first non-foldable area NFA3 and the second non-patterned portion NPP2 corresponding to the second non-foldable area NFA4. The patterned portion PP may be disposed between the first and second non-patterned portions NPP1 and NPP2.

The patterned portion PP may include the plurality of groove patterns GP and the plurality of lower groove patterns UGP. The groove pattern GP may be in the groove shape recessed from the top surface of the patterned glass P-PG. The lower groove pattern UGP may be in the groove shape recessed from the bottom surface of the patterned glass P-PG.

Each of the groove patterns GP and the lower groove patterns UGP may have the stripe shape extending in the direction parallel to the folding axis FX2 (see FIG. 5B) (i.e., the first direction DR1) in a plan view or when viewed in the third direction DR3. The groove patterns GP may be arranged to be spaced apart from each other in the second direction DR2, and the lower groove patterns UGP may be arranged to be spaced apart from each other in the second direction DR2.

As described above with respect to the reinforced patterned glass PG in FIG. 6, the pattern defined in the patterned portion PP of the patterned glass P-PG is not limited thereto. Any pattern that allows the folding to be easier by making the patterned portion PP thinner than the non-patterned portions NPP1 and NPP2 may be applied.

The patterned portion PP of the patterned glass P-PG may be formed by radiating a laser to the patterned portion PP of the glass substrate to cause a thermal damage within the glass substrate, and performing etching with an alkaline solution (e.g., a NaOH and/or KOH solution) at a high temperature condition.

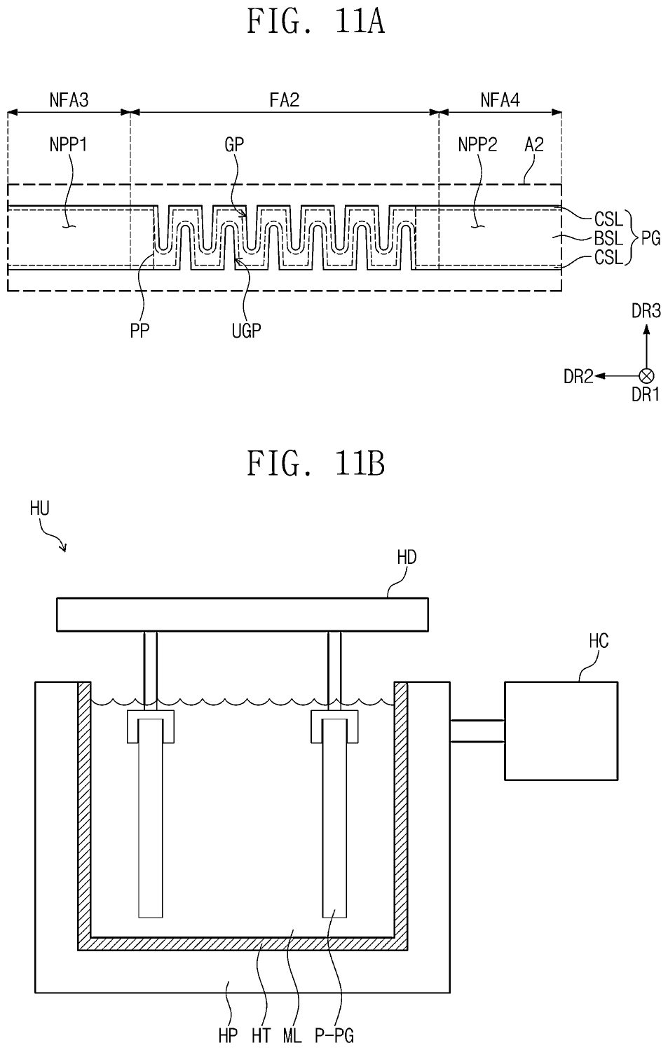

FIGS. 11A and 11B show the forming of the reinforced patterned glass PG (S200). The reinforced patterned glass PG may be formed by chemically strengthening the patterned glass P-PG. The reinforced patterned glass PG may be formed by providing strengthening molten salt to the patterned glass P-PG.

Referring to FIG. 11A, areas of the reinforced patterned glass PG that are chemically strengthened and are adjacent to the surface of the reinforced patterned glass PG may have the compressive stress. The area with the compressive stress adjacent to the surface of the reinforced patterned glass PG may be defined as the compressive stress layer CSL. Regarding the reinforced patterned glass PG, the contents described above in FIGS. 6 to 8 may be equally applied.

FIG. 11B schematically shows an embodiment of an ion exchange device that chemically strengthens the patterned glass P-PG via an ion exchange. A strengthening treatment unit HU may be used to provide the strengthening molten salt to the patterned glass P-PG. The patterned glass P-PG may be immersed in a strengthening molten salt ML using the strengthening treatment unit HU. The strengthening treatment unit HU may include a tank HT for containing the strengthening molten salt ML therein, a heater HP disposed to surround the tank HT and for applying heat to the strengthening molten salt ML in the tank HT, a driver HD that fixes the patterned glass P-PG and moves the patterned glass P-PG in a vertical direction to immerse the patterned glass PG in the strengthening molten salt ML, and a controller HC that controls an operation of the strengthening treatment unit HU. The controller HC may control a temperature of the strengthening molten salt ML contained in the tank HT.

In an embodiment, for example, the controller HC may control the heater HP to heat the strengthening molten salt ML at a certain temperature and maintain the temperature of the strengthening molten salt ML at the heated temperature. The heater HP may provide heat to heat the strengthening molten salt ML, or the heater HP may function as an insulator to maintain the temperature of the heated strengthening molten salt ML.

The patterned glass P-PG may be disposed to be entirely immersed in the strengthening molten salt ML. In FIG. 11B, it is shown that the number of patterned glass P-PG provided in the strengthening treatment unit HU is two, but this is merely an example and the number of patterned glass P-PG to be provided in the strengthening treatment unit HU may be one or three or greater.

The strengthening molten salt ML may include the Na⁺ ions and the K⁺ ions. The strengthening molten salt ML may include NaNO₃ and KNO₃. The strengthening molten salt ML may include NaNO₃ and KNO₃ in a molar ratio of about 3:7.

The ion exchange of the patterned glass P-PG may be performed as the strengthening molten salt ML is provided at a temperature equal to or higher than about 340° C. and lower than about 380° C.

As the patterned glass P-PG is chemically strengthened by providing the strengthening molten salt under the above temperature condition, the reinforced patterned glass PG with the compressive stress at the surface equal to or greater than about 150 MPa and equal to or less than about 350 MPa and with the thickness of the compressive stress layer equal to or greater than about 4.0 μm and equal to or less than about 5.5 μm may be formed. As the reinforced patterned glass PG has the surface compressive stress within the above range and the thickness of the compressive stress layer within the above range, the volume change of the patterned portion PP and the difficulty in correcting the refractive index are reduced, thereby improving the visibility.

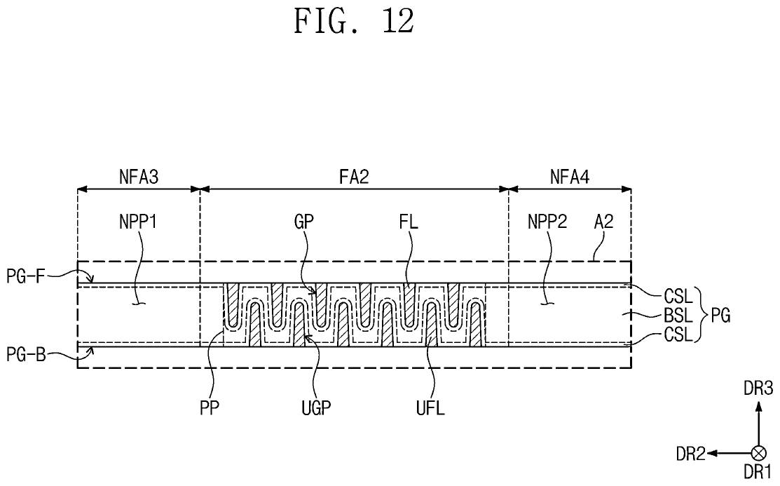

FIG. 12 shows a process of forming the filler FL and the lower filler UFL. The filler FL may fill the groove pattern GP and the lower filler UFL may fill the lower groove pattern UGP. The recessed space defined by the groove pattern GP may be filled by the filler FL, and the recessed space defined by the lower groove pattern UGP may be filled by the lower filler UFL. In an embodiment, the filler FL and the lower filler UFL may be formed by applying and curing a resin.

The reinforced patterned glass PG may have a flat surface because of the filler FL and the lower filler UFL, and may correct or compensate the refractive index change caused by the groove pattern GP and the lower groove pattern UGP.

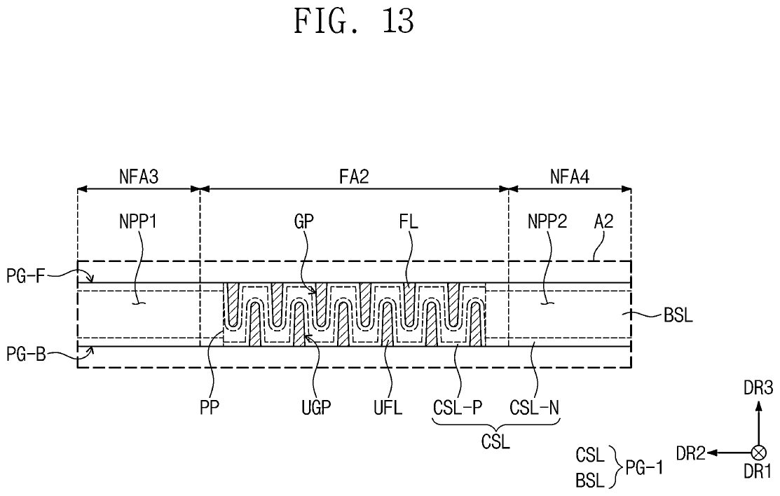

FIG. 13 is a cross-sectional view of a portion of the window WM according to an embodiment of the disclosure. FIG. 13 is an enlarged cross-sectional view of another embodiment of the portion A2 in FIG. 5B. FIG. 13 shows reinforced patterned glass PG-1, the filler FL, and the lower filler UFL among the components of the window WM.

The reinforced patterned glass PG-1 may include the tempered glass including the Na⁺ ions and the K⁺ ions. The concentrations of the Na⁺ ions and the K⁺ ions included in the reinforced patterned glass PG-1 may vary depending on the depth.

The base layer BSL may be a layer with the constant compressive stress (CSL) value. The base layer BSL may have the negative compressive stress value. In other words, the tension may act on the base layer BSL. The compressive stress layer CSL may be the layer with the different compressive stress depending on the depth.

In the reinforced patterned glass PG-1 according to an embodiment, as shown in FIG. 6, the surface compressive stress and the thickness of the compressive stress layer CSL may be different in the patterned portion PP and the non-patterned portions NPP1 and NPP2. In such an embodiment, other features except for the surface compressive stress and the thickness of the compressive stress layer CSL in the patterned portion PP and the non-patterned portions NPP1 and NPP2 are substantially the same as those of the reinforced patterned glass PG described above with reference to FIG. 6, and any repetitive detailed description thereof will be omitted or simplified.

In the patterned portion PP, the surface compressive stress of the reinforced patterned glass PG-1 may be equal to or greater than about 150 MPa and equal to or less than about 350 MPa. When the surface compressive stress is within the above range, durability of the patterned portion PP may be secured and the volume change and the refractive index change resulting from the chemical strengthening may be minimized. Specifically, when the surface compressive stress of the patterned portion PP is less than about 150 MPa, strength of the reinforced patterned glass PG-1 for the application to the window WM may not be sufficient. When the chemically strengthening is performed such that the surface compressive stress of the patterned portion PP exceeds about 350 MPa, the reinforced patterned glass PG-1 becomes curved because of the volume change of the patterned portion PP and the difficulty in correcting the refractive index increases, which may cause the visibility problem.

In the non-patterned portions NPP1 and NPP2, the surface compressive stress of the reinforced patterned glass PG-1 may be set as needed. In an embodiment, for example, in the non-patterned portions NPP1 and NPP2, the surface compressive stress of the reinforced patterned glass PG-1 may be equal to or greater than about 650 MPa and equal to or less than about 850 MPa.

The total thickness t_{PG} of the reinforced patterned glass PG may be equal to or greater than about 100 μm and equal to or less than about 400 km. In this regard, the total thickness t_{PG} of the reinforced patterned glass PG may mean the thickness of the non-patterned portions NPP1 and NPP2. A thickness t_{CSL-P} of a compressive stress layer CSL-P of the patterned portion PP may be less than a thickness t_{CSL-N} of a compressive stress layer CSL-N of the non-patterned portions NPP1 and NPP2. Therefore, while chemically strengthening the non-patterned portions NPP1 and NPP2 as desired, the volume change and the refractive index change of the patterned portion PP may be minimized.

The thickness t_{CSL} of the compressive stress layer CSL may be equal to or greater than about 1% and equal to or less than about 5.5% of the thickness of the non-patterned portions NPP1 and NPP2. The thickness t_{CSL-P} of the compressive stress layer CSL-P of the patterned portion PP may be equal to or greater than 4.0 μm and equal to or less than about 5.5 μm. When the thickness t_{CSL-P} of the compressive stress layer CSL-P of the patterned portion PP is within the above range, the volume change and the refractive index change of the patterned portion PP are small, thereby improving the visibility and reducing the difficulty of correcting the refractive index. Specifically, when the thickness t_{CSL-P} of the compressive stress layer CSL-P of the patterned portion PP is less than about 4.0 km, it may be difficult to suppress the growth of the cracks when the cracks occur. When the thickness t_{CSL-P} of the compressive stress layer CSL-P of the patterned portion PP exceeds about 5.5 μm, the reinforced patterned glass PG-1 becomes curved because of the volume change of the patterned portion PP and the difficulty of correcting the refractive index increases, which may cause the visibility problem.

The thickness t_{CSL-N} of the compressive stress layer CSL-N of the non-patterned portions NPP1 and NPP2 may be set differently if desired. In an embodiment, for example, the thickness t_{CSL-N} of the compressive stress layer CSL-N of the non-patterned portions NPP1 and NPP2 may be equal to or greater than about 6.0 μm and equal to or less than about 8.0 μm, but the disclosure may not be limited thereto.

The reinforced patterned glass PG-1 in an embodiment may be manufactured by chemically strengthening entire surfaces of the patterned glass and then weakening strengthened properties of the patterned portion PP.

The full-scale chemical strengthening may be done by providing the strengthening molten salt ML (see FIG. 11B) to the patterned glass P-PG (see FIG. 10) before the chemical strengthening. For example, the strengthening molten salt ML (see FIG. 11B) may include 100 mol % of KNO₃ and may be provided under a temperature condition of 370° C., so that the ion exchange between the patterned glass P-PG (see FIG. 10) and the strengthening molten salt ML (see FIG. 11B) may be performed.

The weakening of the strengthened properties of the patterned portion PP may be performed by wet etching only the patterned portion PP while masking the non-patterned portions NPP1 and NPP2 after the entire surfaces of the patterned glass are chemically strengthened. By wet etching only the patterned portion PP with a hydrofluoric acid-based solution, a depth of the compressive stress layer and the surface compressive stress of the patterned portion PP may be reduced. In an embodiment, for example, the depth of the compressive stress layer in the patterned portion PP may be reduced by a range equal to or greater than about 1.0 μm and equal to or less than about 2.0 μm.

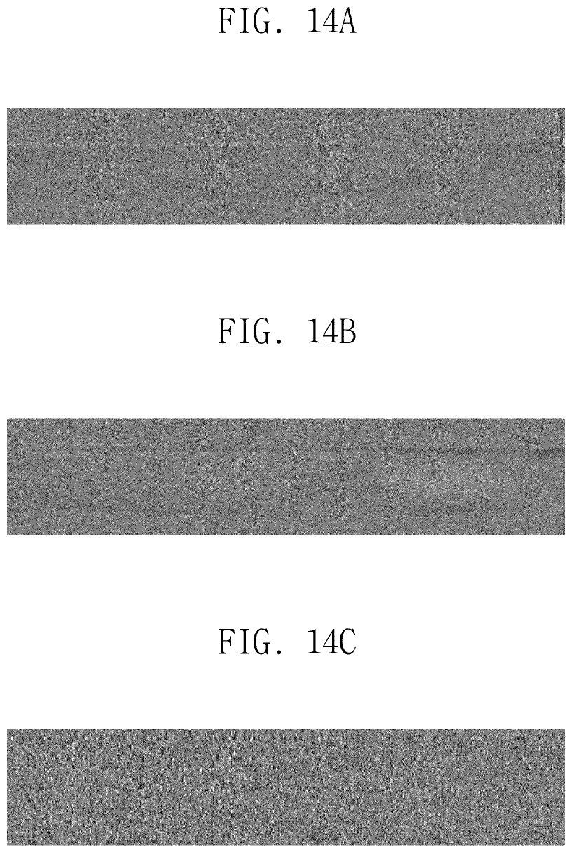

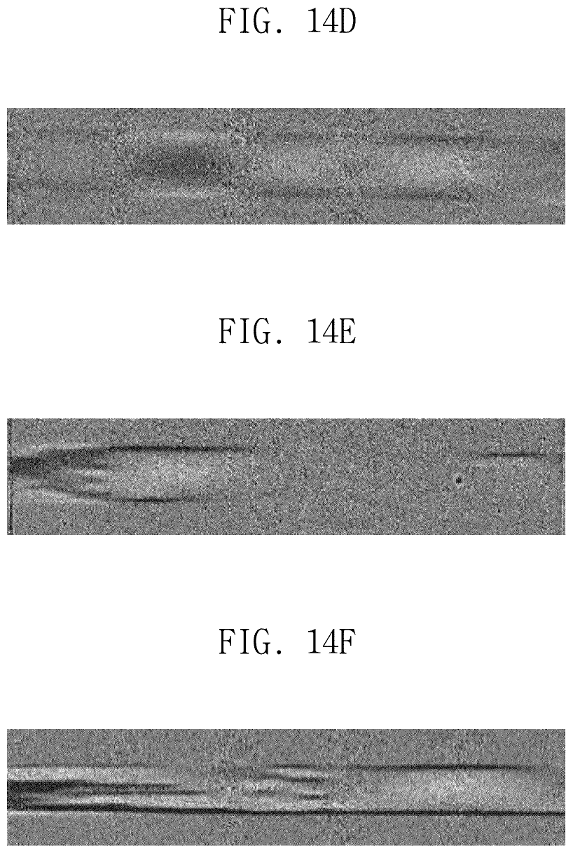

FIGS. 14A to 14F are images showing results of evaluating deformation of a patterned portion of reinforced patterned glass according to Present Examples and Comparative Examples, respectively.

Hereinafter, the results of evaluating the properties of the reinforced patterned glass according to an embodiment of the disclosure will be described, referring to Present Examples and Comparative Examples. Additionally, Present Examples shown below are examples to help understand the disclosure, and the scope of the disclosure is not limited thereto.

The reinforced patterned glass was chemically strengthened by providing the strengthening molten salt including NaNO₃ and KNO₃ in the molar ratio of about 3:7. Present Examples 1 and 2 and Comparative Examples 2 to 4 are chemically strengthened under different strengthening temperature conditions, thereby having different compressive stresses and thicknesses of the compressive stress layer. Comparative Example 1 is patterned glass in a state that has not been chemically strengthened, and serves as a standard for evaluating the deformation of the patterned portion.

Table 1 shows the strengthening temperatures, and the resulting compressive stresses and thicknesses of the compressive stress layer of Present Examples 1 and 2 and Comparative Examples 2 to 4.

TABLE 1

| | Strengthening | Compressive | Compressive stress |
|---|---|---|---|
| | temperature | stress | layer thickness |
| | (° C.) | (MPa) | (μm) |
| Present Example 1 | 360 | 345 | 4.1 |
| Present Example 2 | 370 | 350 | 4.9 |
| Comparative | 380 | 358 | 5.5 |
| Example 2 | | | |
| Comparative | 390 | 367 | 6.0 |
| Example 3 | | | |
| Comparative | 410 | 380 | 7.0 |
| Example 4 | | | |

Table 2 shows the results of evaluating the patterned portion of Present Examples 1 and 2 and Comparative Examples 1 to 4. The patterned portion deformation was evaluated using a surface analyzer Optimap PSD (Phase Stepped Deflectometry, Rhopoint). Values of Kc, Kd, and Ke in Table 2 denote values measured at resolutions of wavelengths in ranges from about 1.0 mm to about 3.0 mm, about from 3.0 mm to about 10.0 mm, and from about 10.0 mm to about 30.0 mm, respectively. The closer the values of Kc, Kd, and Ke are to the values of Kc, Kd, and Ke of Comparative Example 1, in which there is no deformation of the patterned portion because of no chemical strengthening, the less deformation of the patterned portion may be evaluated.

TABLE 2

| | Kc | Kd | Ke |
|---|---|---|---|
| Present Example 1 | 0.7 | 0.6 | 0.2 |
| Present Example 2 | 1.0 | 0.8 | 0.4 |
| Comparative Example 1 | 0.7 | 0.4 | 0.2 |
| Comparative Example 2 | 2.6 | 1.8 | 1.0 |
| Comparative Example 3 | 3.4 | 3.3 | 1.0 |
| Comparative Example 4 | 8.8 | 6.2 | 1.4 |

FIG. 14A is an image of the patterned portion of Present Example 1, FIG. 14B is an image of the patterned portion of Present Example 2, FIG. 14C is an image of the patterned portion of Comparative Example 1, FIG. 14D is an image of the patterned portion of Comparative Example 2, FIG. 14E is an image of the patterned portion of Comparative Example 3, and FIG. 14F is an image of the patterned portion of Comparative Example 4.

Referring to FIG. 14C, no deformation is recognized in the patterned portion of the patterned glass of Comparative Example 1 that is not chemically strengthened.

Referring to FIGS. 14A to 14C and Table 2 together, the reinforced patterned glass of Present Example 1 and Present Example 2, which are chemically strengthened at the strengthening temperatures based on the disclosure and have specific compressive stresses and thicknesses of the compressive stress layer, have Kc to Ke values similar to those of the patterned glass of Comparative Example 1, and no deformation of the patterned portion is recognized therefrom.

Referring to FIGS. 14D to 14F and Table 2 together, Comparative Examples 2 to 4, which are chemically strengthened at temperatures higher than the strengthening temperatures based on the disclosure and have specific compressive stresses and thicknesses of the compressive stress layer, have Kc to Ke values that are very different from the Kc to Ke values of the patterned glass of Comparative Example 1, and the deformation of the patterned portion is recognized therefrom.

According to the embodiments of the disclosure, as described herein, the window includes the reinforced patterned glass with the little changes in the volume and the refractive index of the patterned portion, so that the visibility of the window may be improved.

In embodiments of the disclosure, the display device includes the reinforced patterned glass with the little changes in the volume and the refractive index of the patterned portion, so that the visibility of the display device may be improved.

In embodiments of a window manufacturing method according to the disclosure, the patterned glass may be chemically strengthened such that the volume change and the refractive index change of the patterned portion are small, so that the window with the improved visibility may be manufactured.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A window comprising:
a reinforced patterned glass including a patterned portion, in which a groove pattern is defined, and a non-patterned portion adjacent to the patterned portion,
wherein the reinforced patterned glass includes:
a base layer; and
a compressive stress layer disposed on a top surface and a bottom surface of the base layer,
wherein a compressive stress at a surface of the reinforced patterned glass measured by an ASTM C770-16 method is equal to or greater than about 150 MPa and equal to or less than about 350 MPa,
wherein a thickness of the compressive stress layer is equal to or greater than about 1% of a thickness of the non-patterned portion and equal to or less than about 5.5% of the thickness of the non-patterned portion.

2. The window of claim 1, wherein the reinforced patterned glass includes Na⁺ ions and K⁺ ions.

3. The window of claim 1, wherein a modulus of the reinforced patterned glass is equal to or greater than about 400 MPa and equal to or less than about 700 MPa.

4. The window of claim 1, wherein the thickness of the non-patterned portion is equal to or greater than about 100 μm and equal to or less than about 400 μm.

5. The window of claim 1, wherein the thickness of the compressive stress layer is equal to or greater than about 4.0 μm and equal to or less than about 5.5 μm.

6. The window of claim 1, wherein the groove pattern includes a plurality of grooves defined in a top surface and a bottom surface of the reinforced patterned glass.

7. The window of claim 6, further comprising:
a filler filled in recessed spaces defined by the plurality of grooves.

8. The window of claim 1, further comprising:
a window protecting layer disposed on the reinforced patterned glass.

9. A window comprising:
a reinforced patterned glass including a patterned portion, in which a groove pattern is defined, and a non-patterned portion adjacent to the patterned portion,
wherein the reinforced patterned glass includes:
a base layer; and
a compressive stress layer disposed on a top surface and a bottom surface of the base layer,
wherein a compressive stress at a surface of the patterned portion is less than a compressive stress at a surface of the non-patterned portion.

10. The window of claim 9, wherein the compressive stress at the surface of the patterned portion measured by an ASTM C770-16 method is equal to or greater than about 150 MPa and equal to or less than about 350 MPa.

11. The window of claim 9, wherein a thickness of a compressive stress layer of the patterned portion is less than a thickness of a compressive stress layer of the non-patterned portion.

12. The window of claim 9, wherein a thickness of a compressive stress layer of the patterned portion is equal to or greater than about 1% of a thickness of the non-patterned portion and equal to or less than about 5.5% of the thickness of the non-patterned portion.

13. The window of claim 12, wherein the thickness of the compressive stress layer of the patterned portion is equal to or greater than about 4.0 μm and equal to or less than about 5.5 μm.

14. The window of claim 9, wherein the reinforced patterned glass includes Na⁺ ions and K⁺ ions.

15. The window of claim 9, wherein a modulus of the reinforced patterned glass is equal to or greater than about 400 MPa and equal to or less than about 700 MPa.

16. The window of claim 9, wherein a thickness of the non-patterned portion is equal to or greater than about 100 μm and equal to or less than about 400 μm.

17. The window of claim 9, wherein the groove pattern includes a plurality of grooves defined in a top surface and a bottom surface of the reinforced patterned glass.

18. The window of claim 17, further comprising:
a filler filled in recessed spaces defined by the plurality of grooves.

19. A display device comprising:
a display module including a foldable area foldable around a folding axis on a plane and a non-foldable area adjacent to the foldable area; and
a window disposed on the display module, wherein the window includes a reinforced patterned glass including a patterned portion corresponding to the foldable area and including a groove pattern defined therein and a non-patterned portion corresponding to the non-foldable area,
wherein the reinforced patterned glass includes:
a base layer; and
a compressive stress layer disposed on a top surface and a bottom surface of the base layer,
wherein a compressive stress at a surface of the patterned portion measured by an ASTM C770-16 method is equal to or greater than about 150 MPa and equal to or less than about 350 MPa,
wherein a thickness of a compressive stress layer of the patterned portion is equal to or greater than about 1% of a thickness of the non-patterned portion and equal to or less than about 5.5% of the thickness of the non-patterned portion.

20. The display device of claim 19, wherein a compressive stress at a surface of the non-patterned portion measured by the ASTM C770-16 method is equal to or greater than about 150 MPa and equal to or less than about 350 MPa,
wherein a thickness of a compressive stress layer of the non-patterned portion is equal to or greater than about 1% of the thickness of the non-patterned portion and equal to or less than about 5.5% of the thickness of the non-patterned portion.

21. The display device of claim 19, wherein the compressive stress at the surface of the patterned portion is less than a compressive stress at a surface of the non-patterned portion,
wherein the thickness of the compressive stress layer of the patterned portion is less than a thickness of a compressive stress layer of the non-patterned portion.

22. A method for manufacturing a window, the method comprising:
preparing a patterned glass including a patterned portion including a groove pattern defined therein and a non-patterned portion adjacent to the patterned portion; and
forming a reinforced patterned glass by providing a strengthening molten salt to the patterned glass at a temperature equal to or higher than about 340° C. and lower than about 380° C.,
wherein the strengthening molten salt includes NaNO₃ and KNO₃ in a molar ratio of about 3:7.

23. The method of claim 22, wherein the reinforced patterned glass includes a compressive stress layer,
wherein a compressive stress at a surface of the reinforced patterned glass measured by an ASTM C770-16 method is equal to or greater than about 150 MPa and equal to or less than about 350 MPa,
wherein a thickness of the compressive stress layer is equal to or greater than about 1% of a thickness of the non-patterned portion and equal to or less than about 5.5% of the thickness of the non-patterned portion.

24. The method of claim 23, wherein the thickness of the compressive stress layer is equal to or greater than about 4.0 μm and equal to or less than about 5.5 μm.
